(19) United States
(12) Patent Application Publication
(10) Pub. No.: US 2012/0176077 A1
(43) Pub. Date: Jul. 12, 2012

(54) SOLAR CELL MODULE HAVING WHITE BACK SHEET

(75) Inventors: Seung Yun OH, Gyeonggi-do (KR); Jin Mun Ryu, Gyeonggi-do (KR); Jae Hoon Kim, Seoul (KR); In Taek Song, Gyeonggi-do (KR); Tae Young Kim, Seoul (KR)

(73) Assignee: Samsung Electro-Mechanics Co., Ltd., Suwon (KR)

(21) Appl. No.: 13/343,416

(22) Filed: Jan. 4, 2012

(30) Foreign Application Priority Data
Jan. 7, 2011 (KR) 10-2011-0001721

(51) Int. Cl. H01M 10/46; H01L 31/0224; H01L 31/0232

(52) U.S. Cl. 320/101; 136/259; 136/256

(57) ABSTRACT

The present invention relates to a solar cell module having a white back sheet. According to one aspect of the present invention, provided is a solar cell module having a white back sheet including: a solar cell; an encapsulation sheet for covering and protecting an upper part of the solar cell while transmitting light; and a back sheet for supporting the solar cell and having a white reflection layer for reflecting the light transmitted through the solar cell, wherein the light reflected from the white reflection layer of the back sheet is reused to be photoelectrically converted by the solar cell.

### CROSS-REFERENCE TO RELATED APPLICATIONS

Claim and incorporate by reference domestic priority application and foreign priority application as follows:

### Cross Reference to Related Application

This application claims the benefit under 35 U.S.C. Section 119 of Korean Patent Application Serial No. 10-2011-0001721, entitled filed Jan. 7, 2011, which is hereby incorporated by reference in its entirety into this application.

### BACKGROUND OF THE INVENTION

1. Field of the Invention

The present invention relates to a solar cell module having a white back sheet, and more particularly, to a solar cell module capable of improving energy conversion efficiency by having a white back sheet to reuse light transmitted through a solar cell.

2. Description of the Related Art

In recent times, interest and market for renewable energy are significantly growing due to issues such as rising oil prices, limitations of fossil fuels, and environment, and the renewable energy has been applied to a wide range from power generation to general electronic devices. Among them, research and, development of solar cells as a clean energy source are actively in progress.

The solar cell is an element for converting light energy into electrical energy using a photoelectric effect or a photovoltaic effect. The solar cells are classified into silicon solar cells, thin film solar cells, dye-sensitized solar cells, organic polymer solar cells, and so on according to constituents. In general, these solar cells consist of semiconductors forming a p-n junction, and a solar cell module is formed by connecting the solar cells in series or parallel according to required electrical capacity.

When forming a front electrode of the solar cell, a shadow generated by an electrode line causes a reduction in solar incident area and thus exerts a bad influence on efficiency of the solar cell. Due to this reason, many back contact solar cells as silicon solar cells have been developed.

Further, solar energy conversion efficiency is also remarkably improved due to the development of technology for solar cells, and thus high efficiency cells with an efficiency of more than 23% in laboratory conditions have been developed.

This solar cell module receives light from the sun. Most of the light energy is used to generate electron-hole pairs by combining electrons and holes as carriers of a p-type semiconductor and an n-type semiconductor of the solar cell and some of them are absorbed into a back sheet which supports a back surface of the solar cell. At this time, it is common that the back sheet, which supports the back surface of the solar cell, is a dark color such as black or navy in consideration of color combination of the solar cell module and another set. However, black is a color with very low reflectance of about 3%. Since this black back sheet has low light reflectance, it has difficulty in generating electron-hole pairs and reusing some of the light transmitted through the semiconductors.

### SUMMARY OF THE INVENTION

The present invention has been invented in order to overcome the above-described problems and it is, therefore, an object of the present invention to provide a solar cell module having a white back sheet for using light, which is absorbed into a back sheet for supporting a solar cell in a solar cell module structure and lost, in generating electron-hole pairs again by using a back sheet with high reflectance.

Further, in accordance with another aspect of the present invention, it is another object of the present invention to provide a solar cell module capable of being used as portable and mounted to a portable mobile device and further capable of charging a secondary battery of a mobile device by connecting one or two or more solar cells.

In accordance with one aspect of the present invention to achieve the object, there is provided a solar cell module having a white back sheet including: a solar cell; an encapsulation sheet for covering and protecting an upper part of the solar cell while transmitting light; and a back sheet for supporting the solar cell and having a white reflection layer for reflecting the light transmitted through the solar cell, wherein the light reflected from the white reflection layer of the back sheet is reused to be photoelectrically converted by the solar cell.

Preferably, in accordance with another aspect, the back sheet consists of a PCB substrate, and the white reflection layer is a white PSR layer of the PCB substrate.

Further, preferably, in accordance with another aspect of the present invention, the solar cell is a back contact cell, and the back sheet is a polymer resin sheet having the white reflection layer.

More preferably, the encapsulation sheet covers and protects the upper part and a lower part of the solar cell, and the back sheet is attached to the encapsulation sheet which covers the lower part of the solar cell.

Further, preferably, the polymer resin sheet includes one of EVA, PVB, epoxy, and acrylic.

Further, preferably, in accordance with another aspect of the present invention, the solar cell has a back electrode, and a plurality of solar cells are connected in series on the back sheet.

Further, preferably, in accordance with another aspect of the present invention, the solar cell module further includes a front cover sheet attached to a front surface of the encapsulation sheet which covers the upper part of the solar cell.

Preferably, in accordance with another aspect of the present invention, the above-described solar cell module is mounted to a mobile device.

Further, preferably, the solar cell module charges a secondary battery cell of the mobile device with generated electrical energy.

Although not explicitly mentioned as one aspect of the present invention, embodiments of the present invention according to various possible combinations of the above-mentioned technical features can be apparently implemented by those skilled in the art.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing a solar cell module in accordance with an embodiment of the present invention; and

FIG. 2 is a view schematically showing a solar cell module in accordance with another embodiment of the present invention.

### DETAILED DESCRIPTION OF THE PREFERABLE EMBODIMENTS

Embodiments of the present invention to achieve the above-described objects will be described with reference to the accompanying drawings. In this description, the same elements are represented by the same reference numerals, and additional description which is repeated or limits interpretation of the meaning of the invention may be omitted.

Before the detailed description, in this specification, when an element is referred to as being simply “connected” or “coupled” to another element, it should be understood that it can be “directly” connected or coupled to the other element or connected or coupled to the other element with another element interposed therebetween unless being contradictory to the concept of the invention.

Although the singular form is used in this specification, it should be noted that the singular form can be used as the, concept representing the plural form unless being contradictory to the concept of the invention or clearly interpreted otherwise. In this specification, it should be understood that the terms such as “having”, “including”, and “comprising” used herein do not preclude existence or addition of one or more other features or elements or combination thereof.

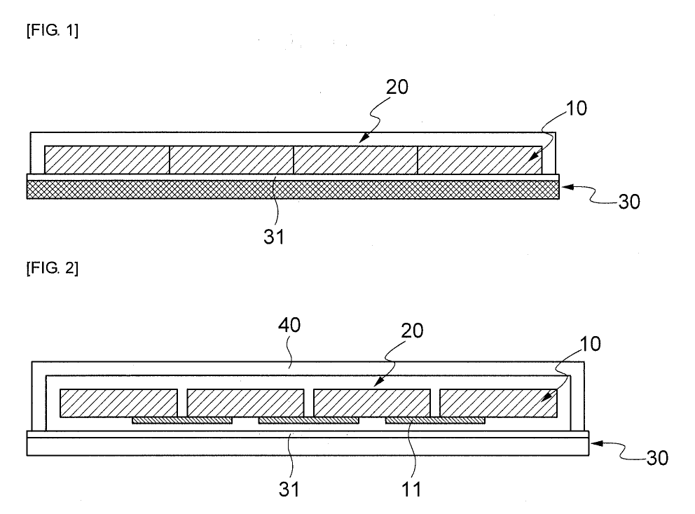

FIG. 1 is a view schematically showing a solar cell module in accordance with an embodiment of the present invention, and FIG. 2 is a view schematically showing a solar cell module in accordance with another embodiment of the present invention.

Embodiments of the present invention will be described in detail with reference to FIGS. 1 and 2.

Referring to FIGS. 1 and 2, a solar cell module having a white back sheet in accordance with one aspect of the present invention is formed by sequentially laminating an encapsulation sheet 20, a solar cell 10, and a back sheet 30 from the top.

Various types of solar cells such as silicon solar cells, dye-sensitized solar cells, and organic polymer solar cells may be applied as the solar cell, and preferably, the silicon solar cell is used. Although not shown, the solar cell forms a p-n junction of a p-type semiconductor and an n-type semiconductor and generates electron-hole pairs by receiving light to combine electrons and holes as carriers of the p-type semiconductor and the n-type semiconductor. Most of the light incident to the solar cell 10 by transmitting through the encapsulation sheet 20 generates electron-hole pairs to make electrical energy, but some of them transmit the n-type semiconductor and the p-type semiconductor.

Preferably, the solar cell 10 is a back contact solar cell. The back contact solar cell is manufactured by forming electrodes to be in electrical contact with a back surface of a cell, for example, a p-type region and an n-type region.

Since the solar cells are described in many documents and widely known to the art, more detailed description will be omitted.

The encapsulation sheet 20 transmits light to allow light energy to reach the solar cell 10 and performs a function of covering and protecting an upper part of the solar cell 10.

Preferably, when describing an embodiment of the present invention with reference to FIG. 2, the encapsulation sheet 20 covers and protects a lower part of the solar cell 10 as well as the upper part of the solar cell 10. Further, preferably, the encapsulation sheet 20 is a polymer resin sheet and more preferably includes one of EVA, PVB, epoxy, and acrylic. Since it is already described in many documents and widely known to those skilled in the art that the encapsulation sheet 20 is formed of a polymer resin sheet, detailed description will be omitted.

In the present invention, the back sheet 30 supports a back surface of the solar cell 10 and includes a white reflection layer 31 for reflecting the light transmitted through the solar cell 10. In the present invention, the light reflected from the white reflection layer 31 of the back sheet 30 is reused to be photoelectrically converted by the solar cell 10.

Preferably, in accordance with an embodiment, the back sheet 30 consists of a PCB substrate. At this time, the white reflection layer 31 is a white PSR layer of the PCB substrate. The white PSR layer can be obtained by coating white during PSR coating.

Further, preferably, in accordance with another embodiment, the back sheet 30 is a polymer resin sheet having the white reflection layer 31. More preferably, the polymer resin sheet includes one of EVA, PVB, epoxy, and acrylic. The white reflection layer 31 of the back sheet 30, the polymer resin sheet, may be formed by various methods such as application or coating and provided by forming the polymer resin sheet white.

Meanwhile, preferably, referring to FIG. 2, when the encapsulation sheet 20 covers the lower part of the solar cell 10 as well as the upper part of the solar cell 10, the back sheet 30 is attached to the encapsulation sheet 20 which covers the lower part of the solar cell 10.

In the present invention, by using the back sheet with high reflectance as above, the light energy reaching the back sheet by transmitting through the semiconductors is reflected to the surface of the solar cell so that electron-hole pairs are generated again to make electrical energy.

As described above, in the present invention, a basic structure of the solar cell module is the same as that of a conventional solar cell module in which a solar cell module 10 is connected to a back sheet 30 using a polymer resin sheet such as EVA or epoxy or a PCB and an encapsulation sheet 20 is molded on the solar cell 10 to protect the solar cell 10. However, the present invention can improve maximum voltage and current, which can be generated by the solar cell, by manufacturing the back sheet 30 with a white color having high reflectance to generate electron-hole pairs and reflecting the light transmitted through the semiconductors to secondarily generate electron-hole pairs.

Referring to FIG. 2, when describing another preferable embodiment, a bus-bar 11, which forms an electrode line of the back contact solar cell 10, connects the back electrodes of the solar cells 10 in series so that a plurality of solar cells 10 are connected in series on the back sheet 30. Preferably, although not shown, metal electrodes are alternatively disposed in positive (+) and negative (−) regions of the back surface of the solar cell 10, and when connecting the solar cells 10 in series, the bus-bar 11, which connects the electrodes of one polarity in one solar cell 10, is connected to the bus-bar 11, which connects the electrodes of the other polarity in adjacent another solar cell 10 so that the plurality of solar cells 10 can be connected in series.

Further, referring to FIG. 2, preferably, in accordance with another embodiment of the present invention, the solar cell module further includes a front cover sheet 40 attached to a front surface of the encapsulation sheet 20 which covers the upper part of the solar cell 10. The front cover sheet 40 may be a polymer resin sheet or transparent glass.

Although not shown, preferably, in accordance with another embodiment of the present invention, the solar cell module having the white back sheet 30 is mounted to a mobile device (not shown).

Preferably, the solar cell module mounted to the mobile device charges a secondary battery cell (not shown) of the mobile device with generated electrical energy.

In accordance with one aspect of the present invention, it is possible to simply obtain a high efficiency solar cell module by using a back sheet with high reflectance to use light, which is absorbed into a back sheet for supporting a solar cell in a solar cell module structure and lost, in generating electron-hole pairs again.

Further, in accordance with another aspect of the present invention, it is possible to provide a solar cell module capable of being used as portable and mounted to a portable mobile device and further capable of charging a secondary battery of a mobile device by connecting one or two or more solar cells.

It is apparent that various effects which have not been directly mentioned according to the various embodiments of the present invention can be derived by those skilled in the art from various constructions according to the embodiments of the present invention.

The preferable embodiments of the present invention were described above with reference to the accompanying drawings. The accompanying drawings and the above-described embodiments are provided as examples to help understanding of those skilled in the art. Therefore, the various embodiments of the present invention may be embodied in different forms in a range without departing from the essential concept of the present invention, and the above-described embodiments should be regarded as illustrative rather than restrictive. Accordingly, the scope of the present invention should be interpreted from the above-described embodiments rather than the invention defined in the claims, and it is apparent that various modifications, substitutions, and equivalents by those skilled in the art are included in the scope of the present invention.

What is claimed is:

1. A solar cell module comprising:
a solar cell;
an encapsulation sheet for covering and protecting an upper part of the solar cell while transmitting light; and
a back sheet for supporting the solar cell and having a white reflection layer for reflecting the light transmitted through the solar cell, wherein the light reflected from the white reflection layer of the back sheet is reused to be photoelectrically converted by the solar cell.

2. The solar cell module according to claim 1, wherein the back sheet consists of a PCB substrate, and the white reflection layer is a white PSR layer of the PCB substrate.

3. The solar cell module according to claim 1, wherein the solar cell is a back contact cell, and the back sheet is a polymer resin sheet having the white reflection layer.

4. The solar cell module according to claim 3, wherein the encapsulation sheet covers and protects the upper part and a lower part of the solar cell, and the back sheet is attached to the encapsulation sheet which covers the lower part of the solar cell.

5. The solar cell module according to claim 3, wherein the polymer resin sheet comprises one of EVA, PVB, epoxy, and acrylic.

6. The solar cell module according to claim 1, wherein the solar cell comprises a back electrode, and a plurality of solar cells are connected in series on the back sheet.

7. The solar cell module according to claim 1, further comprising:
a front cover sheet attached to a front surface of the encapsulation sheet which covers the upper part of the solar cell.

8. The solar cell module according to one of claim 1, wherein the solar cell module is mounted to a mobile device.

9. The solar cell module according to claim 8, wherein the solar cell module charges a secondary battery cell of the mobile device with generated electrical energy.
